(19) United States
(12) Patent Application Publication
(10) Pub. No.: US 2008/0138718 A1
(43) Pub. Date: Jun. 12, 2008

(54) Holographic optical recording medium, manufacturing method thereof and holographic optical recording method

(75) Inventors: Rumiko Hayase, Yokohama-shi (JP); Akiko Hirao, Chiba-shi (JP); Kazuki Matsumoto, Kawasaki-shi (JP); Takayuki Tsukamoto, Kawasaki-shi (JP); Urara Ichihara, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Kabushiki Kaisha Toshiba

(21) Appl. No.: 12/011,254

(22) Filed: Jan. 25, 2008

Related U.S. Application Data
(62) Division of application No. 10/872,437, filed on Jun. 22, 2004.

(30) Foreign Application Priority Data
Sep. 30, 2003 (JP) 2003-342231

(51) Int. Cl. G03F 7/004

(52) U.S. Cl. 430/2

(57) ABSTRACT

Disclosed is a holographic optical recording medium comprising a recording layer having a skeleton structure represented by following general formula (A):

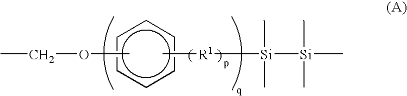

where R¹ denotes an atomic group selected from the group consisting of a linear or branched alkylene group having 1 to 10 carbon atoms and an arylene group having 1 to 10 carbon atoms, it being possible for a halogen atom or an alkoxy group to be substituted in R¹, and each of p and q is 0 or 1.

### CROSS-REFERENCE TO RELATED APPLICATIONS

This application is based upon and claims the benefit of priority from prior Japanese Patent Application No. 2003-342231, filed Sep. 30, 2003, the entire contents of which are incorporated herein by reference.

### BACKGROUND OF THE INVENTION

1. Field of the Invention

The present invention relates to an optical recording medium, particularly, to a holographic optical recording medium, the manufacturing method thereof, and a holographic optical recording method.

2. Description of the Related Art

In recent years, it has been proposed to use polysilane for forming a recording layer included in a holographic optical recording medium. If the recording layer formed of polysilane is irradiated with ultraviolet light, the Si—Si bond is broken, with the result that the refractive index is reduced, making it possible to record a hologram.

Polysilane used in the past is a solid. A recording layer is formed by coating a substrate with a solution prepared by dissolving the solid polysilane in a suitable solvent. In the volume hologram for recording the data in a three-dimensional directional, the recording layer having a large thickness is advantageous. To be more specific, the recording layer is required to be formed in a thickness of about 200 μm to 1 mm. However, it is impossible to form a recording layer having a desired thickness by the method of coating a substrate with a solution of polysilane. To be more specific, the thickness of the recording layer that can be formed by the coating of a solution is smaller than 10 μm.

In addition, since the change in the refractive index of the recording layer containing polysilane is brought about by the breakage of the backbone chain of the polysilane caused by the light irradiation, the mechanical strength of the recording layer is unavoidably lowered by the decrease in the molecular weight of the polysilane. What should also be noted is that oxygen is coupled with the broken portion in the backbone chain of the polysilane, causing the volume expansion of the recording layer, which also gives rise to a problem.

### BRIEF SUMMARY OF THE INVENTION

According to a one aspect of the present invention, there is provided a holographic optical recording medium, comprising a recording layer having a skeleton structure represented by following general formula (A):

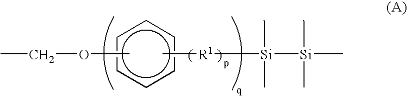

where R¹ denotes an atomic group selected from the group consisting of a linear or branched alkylene group having 1 to 10 carbon atoms and an arylene group having 1 to 10 carbon atoms, it being possible for a halogen atom or an alkoxy group to be substituted in R¹, and each of p and q is 0 or 1.

According to another aspect of the present invention, there is provided a holographic optical recording medium, comprising a recording layer including a skeleton structure represented by following general formula (A) and a photo-polymerizable compound:

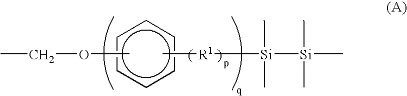

where R¹ denotes an atomic group selected from the group consisting of a linear or branched alkylene group having 1 to 10 carbon atoms and an arylene group having 1 to 10 carbon atoms, it being possible for a halogen atom or an alkoxy group to be substituted in R¹, and each of p and q is 0 or 1.

According to another aspect of the present invention, there is provided a holographic optical recording medium, comprising a recording layer including a skeleton structure containing a three-dimensionally crosslinked polysilane and a photo-polymerizable compound.

According to another aspect of the present invention, there is provided a method for manufacturing a holographic optical recording medium, comprising mixing a polysilane having a hydroxyl group with an epoxy compound so as to prepare a raw material composition for a recording layer having a viscosity at 30° C. in the range of 2 mPa·S to 50 Pa˜S; coating a substrate with the raw material composition for a recording layer so as to obtain a coating layer; and curing the coating layer so as to form a recording layer having a thickness in the range of 50 μm to 2 cm and containing a three-dimensionally crosslinked polysilane.

Further, according to still another aspect of the present invention, there is provided a method for recording a hologram, comprising irradiating a prescribed region of the recording layer included in the holographic optical recording medium with a first light so as to perform the recording, the recording layer having a skeleton structure containing a three-dimensionally crosslinked polysilane and a photo-polymerizable compound; and irradiating the entire surface of the recording layer with a second light having a wavelength shorter than that of the first light.

### BRIEF DESCRIPTION OF THE SEVERAL VIEWS OF THE DRAWING

FIG. 1 is a cross-sectional view schematically showing the construction of a holographic optical recording medium according to one embodiment of the present invention;

FIG. 2 schematically shows the construction of a holographic optical information recording-reproducing apparatus; and

FIG. 3 is a graph showing an example of the holographic angle multiplexing reproduced signal according to one embodiment of the present invention.

### DETAILED DESCRIPTION OF THE INVENTION

An embodiment of the present invention will now be described.

The recording layer included in the holographic optical recording medium according to one embodiment of the present invention has a structural unit represented by general formula (A) given previously. In other words, the recording layer is formed by a three-dimensionally crosslinked polysilane. Because of the crosslinkage, the change in volume is small even if the backbone chain of the polysilane is broken so as to make it possible to suppress the reduction in the mechanical strength of the recording layer.

R¹ included in general formula (A) denotes an alkylene group having 1 to 10 carbon atoms or an arylene group having 1 to 10 carbon atoms. It is possible for the alkylene group to be linear or branched. To be more specific, it is possible for the alkylene group to be a bivalent group having a chain of 1 to 10 methylene groups or to be a branched bivalent group having, for example, a methyl group, an ethyl group, a butyl group or a phenyl group substituted for the hydrogen atom included in the chain of the methylene groups. On the other hand, it is possible to use, for example, a phenylene group, a biphenylene group or a naphthylene group as the arylene group.

It is possible for at least one hydrogen atom included in the alkylene group or the arylene group represented by R¹ to be replaced by a halogen atom or an alkoxy group. The halogen atom noted above includes, for example, a Cl atom, Br atom or an I atom. On the other hand, the alkoxy group noted above includes, for example, a methoxy group, an ethoxy group, a propoxy group and a phenoxy group.

To be more specific, the compound represented by general formula (A) includes, for example, compounds represented by following chemical formulas (1) to (3):

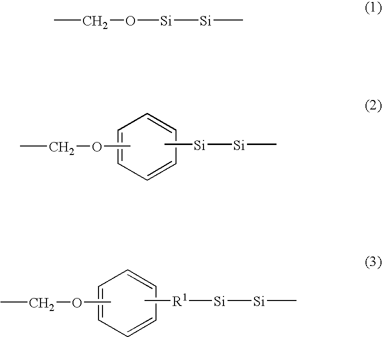

At least one compound represented by the chemical formulas (1), (2) and (3) can be included in the skeleton structure represented by the general formula (A).

The crosslinked polysilane constituting the recording layer included in the holographic optical recording medium according to this embodiment of the present invention can be synthesized by the reaction between, for example, a polysilane having a hydroxyl group and an epoxy compound. It is desirable to use the compounds represented by following general formulas (4) and (5) as the polysilane having a hydroxyl group:

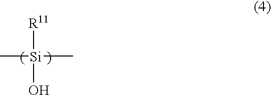

where R¹¹ is a monovalent organic group having 1 to 20 carbon atoms,

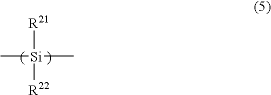

where at least one of R²¹ and R²², which may be the same or different, is an aromatic ring having a hydroxyl group attached thereto, and the other is a hydrogen atom or a monovalent organic group having 1 to 20 carbon atoms.

The monovalent organic group represented by R¹¹ in the general formula (4) includes, for example, aliphatic hydrocarbon groups such as a methyl group, an ethyl group, a propyl group, a butyl group, a pentyl group, a hexyl group, a heptyl group, an octyl group, a nonyl group and a decyl group; an alicyclic hydrocarbon groups such as a cyclobutyl group, a cyclopentyl group and a cyclohexyl group; and aromatic hydrocarbon groups such as a phenyl group and a naphthyl group. It is possible for at least one hydrogen atom included in any of these hydrocarbon groups to be replaced by, for example, a halogen atom or an alkoxy group. Further, it is possible for R¹¹ to represent the monovalent organic group having any of these hydrocarbon group bonded thereto.

It is also possible for the hydrocarbon group exemplified above to be introduced as R²¹ and/or R²² into the polysilane having a hydroxyl group, which is represented by the general formula (5). The aromatic ring contained in at least one of R²¹ and R²² includes, for example, a benzene ring and a naphthalene ring.

To be more specific, the polysilane having a hydroxyl group includes the compounds represented by following chemical formulas (6) to (12):

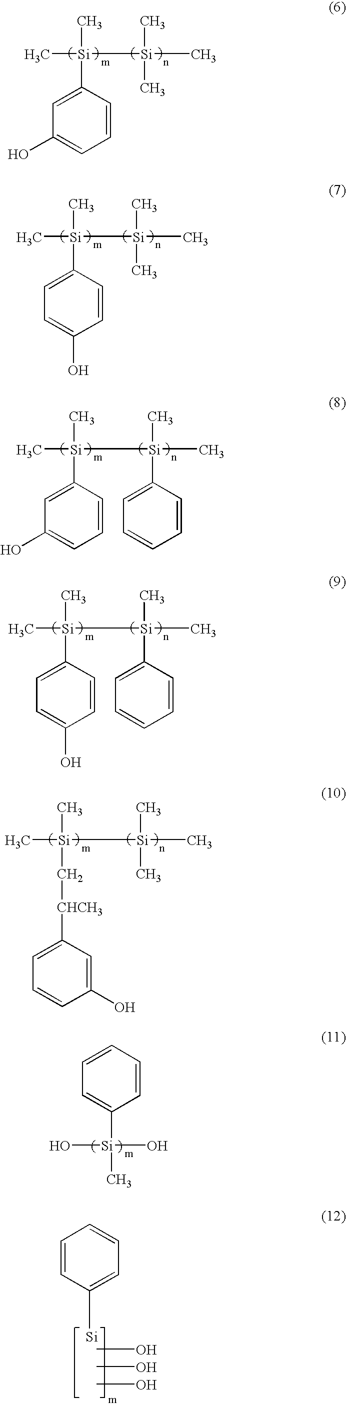

In each of the chemical formulas given above, m is a positive integer, and n is zero or a positive integer. Where n is a positive integer, each of the chemical formulas given above represents a block copolymer or a random copolymer.

It is desirable for the polysilane having a hydroxyl group to have a weight average molecular weight of about 200 to 2,000,000. Where the polysilane has a weight average molecular weight smaller than 200, the cured material tends to be rendered brittle. On the other hand, where the polysilane has a weight average molecular weight exceeding 2,000,000, the cured material tends to be rendered opaque, with the result that the light is scattered so as to make it impossible to perform the recording.

On the other hand, the epoxy compound includes, for example, butane diol diglycidyl ether, diepoxy octane, hexane diol diglycidyl ether, ethyl hexyl glycidyl ether, isobutyl glycidyl ether, phenyl glycidyl ether, naphthyl glycidyl ether, glycidyl benzoate, hydroquinone diglycidyl ether, glycidyl phthalimide, polyethylene glycol diglycidyl ether, polypropylene glycol diglycidyl ether, resorcinol diglycidyl ether, neopentyl glycol diglycidyl ether, diglycidyl ether of bisphenol A, diglycidyl ether of bisphenol F, diglycidyl ether of biphenyl ether and derivatives thereof, tetraglycidyl ether of 2,2′4,4′-tetrahydro benzophenone, N,N-diglycidyl amino glycidoxy benzene, 1,3,5-triglycidoxy benzene, 2,2′,4,4′-tetraglycidoxy biphenyl, 4,4′-bis(2,3-epoxy propoxy)-3,3′,5,5′-tetramethyl biphenyl, N,N,N′,N′-tetraglycidyl amino diphenyl methane, dicyclopentadiene type epoxy resin, 3,4-epoxy cyclohexenyl methyl-3′,4′-epoxy cyclohexene carboxylate, polydimethyl siloxane of epoxy propoxy propyl terminal, and various halogenated epoxy compounds.

The polysilane having a hydroxyl group and the epoxy compound are selected such that the mixture thereof assumes a liquid state at room temperature. It follows that the raw material composition of the recording layer can be prepared by simply mixing the polysilane having a hydroxyl group and the epoxy compound without using a solvent. The raw material composition of the recording layer is required to exhibit a viscosity at 30° C., which is in the range of 2 mPa·S to 50 Pa·S. Where the viscosity at 30° C. is lower than 2 mPa·S, it is difficult to obtain a recording layer having a desired thickness. On the other hand, if the viscosity at 30° C. exceeds 50 Pa·S, problems are generated such that the operability is lowered and that it is difficult to remove the bubbles.

A glass substrate or a plastic substrate is coated with the raw material composition of the recording layer, followed by curing the coated film. As a result, a reaction is carried out between the hydroxyl group bonded to the polysilane and the epoxy compound so as to form a crosslinked polysilane film. It is also possible for the raw material composition of the recording layer to be poured into the clearance between a pair of transparent substrates arranged apart from each other with a spacer interposed therebetween so as to cure the raw material composition of the recording layer. In curing the coated film, it is possible to heat the coated film at temperatures not lower than room temperature, e.g., not higher than about 150° C., or to irradiate the coated film with light of, for example, a mercury lamp or a xenon lamp.

Since the crosslinking reaction can be performed without using a solvent as descried above, it is possible to increase the thickness of the formed film, compared with the case where the substrate is coated with a solution prepared by dissolving the polysilane in a solvent, with the result that it is possible to form a crosslinked polysilane film having a thickness suitable for forming a recording layer of a volume holographic optical recording medium. It is preferable for the recording layer included in the holographic optical recording medium to have a thickness in the range of 50 μm to 2 cm, more preferably 100 μm to 1 cm.

It is desirable for the three-dimensionally crosslinked polysilane film obtained after the curing stage to contain the structure derived from the polysilane having a hydroxyl group in an amount of 10% by weight to 80% by weight. If the amount of the particular structure is smaller than 10% by weight, the sensitivity of the crosslinked polysilane film is lowered, with the result that the time required for the recording is prolonged. On the other hand, if the amount of the structure exceeds 80% by weight, the change in volume caused by the light irradiation is increased, with the result that the film after the light irradiation tends to be rendered brittle. Such being the situation, it is desirable to control the mixing amounts of the polysilane having a hydroxyl group and the epoxy compound in the raw material composition of the recording layer such that the polysilane content of the cured material falls within the range noted above. Incidentally, it is more desirable for the amount of the structure derived from the polysilane having a hydroxyl group, which is contained in the cured material, to be in the range of 20% by weight to 70% by weight.

It is possible to add, as desired, a curing agent to the raw material composition of the recording layer. It is possible to use as the curing agent amines, phenols, organic acid anhydrides and amides, which are known as the epoxy curing agents. To be more specific, the curing agent includes, for example, diethylene triamine, triethylene triamine, tetraethylenepentamine, imino bis-propyl amine, bis(hexamethylene)triamine, 1,3,6-tris aminomethyl hexane, poly-methylene diamine, trimethyl hexamethylene diamine, diethylene glycol bis-propylene diamine, diethyl aminopropyl amine, menthane diamine, isophorone diamine, bis(4-amino-3-methyl cyclohexyl)methane, N-amino ethyl piperazine, m-xylene diamine, m-phenylene diamine, p-phenylene diamine, diamino diphenyl methane, diamino diphenyl sulfone, anhydrous maleic acid, anhydrous succinic acid, tetrahydro anhydrous phthalic acid, methyl tetrahydro anhydrous phthalic acid, anhydrous methyl nadic acid, hexahydro anhydrous phthalic acid, methyl hexahydro phthalic acid, methyl cyclohexene tetracarboxylic acid anhydride, anhydrous phthalic acid, anhydrous trimellitic acid, anhydrous benzophenone tetracarboxylic acid, ethylene glycol bis(anhydrotrimellitate), phenol novolak resin, cresol novolak resin, polyvinyl phenol, terpene phenolic resin, and polyamide resin.

It is also possible to add a curing catalyst, as desired. A basic catalyst and a peroxide known as an epoxy curing catalyst can be used as the curing catalyst. For example, it is possible to use tertiary amines, organic phosphine compounds, imidazole compounds and derivatives thereof as the curing catalyst. To be more specific, the curing catalyst includes, for example, triethanol amine, piperidine, N,N′-dimethyl piperadine, 1,4-diazabicyclo(2,2,2)octane(triethylene diamine), pyridine, picoline, dimethyl cyclohexyl amine, dimethyl hexyl amine, benzyl dimethyl amine, 2-(dimethyl amino methyl)phenol, 2,4,6-tris(dimethyl amino methyl)phenol, DBU (1,8-diazabicyclo(5,4,0 undecene-7) or a phenol salt thereof, trimethyl phosphine, triethyl phosphine, tributyl phosphine, triphenyl phosphine, tri(p-methyl phenyl)phosphine, 2-methyl imidazole, 2,4-dimethyl imidazole, 2-ethyl-4-methyl imidazole, 2-phenyl imidazole, 2-phenyl-4-methyl imidazole, and 2-hepta imidazole. It is also possible to use a latent catalyst such as trifluoro boron amine complex, dicyan diamide, organic acid hydrazide, diamino maleonitrile, a derivative thereof, melamine, a derivative thereof, and amine imide.

The recording layer included in the holographic optical recording medium according to another embodiment of the present invention comprises a structural unit represented by general formula (A) given previously and a photo-polymerizable compound dispersed in the structural unit noted above. The photo-polymerizable compound, the refractive index of which is increased by irradiation with light, is selected from the group consisting of a photo radical polymerizable compound and a photo cationic polymerizable compound. If a prescribed region of the recording layer containing the particular compound is irradiated with a recording light, the photo-polymerizable compounds are collected in a region that is strongly irradiated with the light. As a result, a photopolymerization is carried out so as to form a concentration gradient. It follows that the refractive index is increased in the region that is strongly irradiated with light so as to record the data.

In this case, a first light having a wavelength that permits polymerization of the photo-polymerizable compound without giving any function to the polysilane is used as the recording light. In general, the polysilane is not decomposed in the case of using a light having a wavelength not less than 350 nm, though the decomposition is dependent on the substituent contained in the skeleton structure. After irradiation with the recording light, the entire surface of the recording layer is irradiated with a second light having a short wavelength at which the polysilane is decomposed, i.e., the second light having a wavelength not longer than, for example, 300 nm. As a result, the polysilane is mainly decomposed in the region that was not strongly irradiated with the recording light so as to lower the refractive index. The resultant polymer is not affected at all by the irradiation with the second light. In other words, the region strongly irradiated with the recording light has high concentrations of the photo-polymerizable compound and a high concentration of the polymer formed by polymerization of the photo-polymerizable compound, with the result that the light having a short wavelength tends to be absorbed easily. It follows that a sufficiently high light energy is not imparted to the crosslinked polysilane forming the matrix and, thus, the decomposition of polysilane does not proceed significantly. On the other hand, the region that was not strongly irradiated with the recording light has a low concentration of the photo-polymerizable compound. As a result, the amount of light absorbed by the photo-polymerizable compound is small and, thus, a sufficiently high light energy is imparted to the polysilane, facilitating the decomposition of the polysilane.

Under the circumstances, the contrast between the region having a high refractive index and the region having a low refractive index is increased, making it possible to obtain a hologram having a large dynamic range.

The above-noted effect produced by the photo-polymerizable compound can be obtained regardless of the skeleton structure of the recording layer as far as the recording layer is formed of the three-dimensionally crosslinked polysilane. If the photo-polymerizable compounds are dispersed in the skeleton structure containing the three-dimensionally crosslinked polysilane, it is possible to obtain a recording layer included in the holographic optical recording medium according to still another embodiment of the present invention. The three-dimensionally crosslinked polysilane skeleton other than that represented by general formula (A) given previously includes, for example, the skeleton structure represented by following general formula:

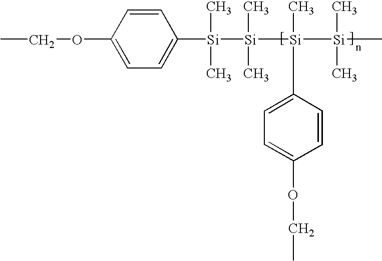

where n is a positive integer.

The photo radical polymerizable compound includes compounds having an ethylenically unsaturated double bond including, for example, an unsaturated carboxylic acid, an unsaturated carboxylic acid ester, an unsaturated carboxylic acid amide, and a vinyl compound. To be more specific, the photo radical polymerizable compound includes, for example, acrylic acid, methyl acrylate, ethyl acrylate, propyl acrylate, butyl acrylate, isobutyl acrylate, 2-ethyl hexyl acrylate, octyl acrylate, lauryl acrylate, stearyl acrylate, cyclohexyl acrylate, bicyclo pentenyl acrylate, phenyl acrylate, isobornyl acrylate, adamanthyl acrylate, methacrylic acid, methyl methacrylate, propyl methacrylate, butyl methacrylate, phenyl methacrylate, phenoxy ethyl acrylate, chlorophenyl acrylate, adamanthyl methacrylate, isobornyl methacrylate, N-methyl acrylate, N,N-dimethyl acryl amide, N,N-dimethyl amino propyl acryl amide, N,N-dimethyl amino ethyl acrylate, styrene, bromo styrene, chloro styrene, vinyl naphthalene, vinyl naphthoate, N-vinyl pyrrolidinone, N-vinyl carbazole, polyethylene glycol diacrylate, polyethylene glycol dimethacrylate, tripropylene glycol diacrylate, propylene glycol trimethacrylate, diaryl phthalate, and triaryl trimellitate.

The photo cationic polymerizable compound includes, for example, an epoxy compound and an oxetane compound. To be more specific, the epoxy compound includes, for example, butane diol glycidyl ether, diepoxy octane, hexane diol glycidyl ether, ethyl hexyl glycidyl ether, isobutyl glycidyl ether, phenyl glycidyl ether, naphthyl glycidyl ether, glycidyl benzoate, hydroquinone glycidyl ether, glycidyl phthalimide, polyethylene glycol diglycidyl ether, polypropylene glycol diglycidyl ether, resorcinol diglycidyl ether, neopentyl glycol diglycidyl ether, diglycidyl ether of bisphenol A, diglycidyl ether of bisphenol F, diglycidyl ether of biphenyl ether and a derivative thereof, tetraglycidyl ether of 2,2′,4,4′-tetrahydroxy benzophenone, N,N-diglycidyl amino glycidoxy benzene, 1,3,5-triglycidoxy benzene, 2,2′,4,4′-tetraglycidoxy biphenyl, 4,4′-bis(2,3-epoxy propoxy)-3,3′,5,5′-tetramethyl biphenyl, N,N,N′,N′-tetraglycidyl amino diphenyl methane, dicyclopentadiene type epoxy resin, 3,4-epoxy cyclohexenyl methyl-3′,4′-epoxy cyclohexene carboxylate, polydimethyl siloxane of epoxy propoxy propyl terminal and various halogenated epoxy compounds.

On the other hand, the oxetane compound includes, for example, 3-ethyl-3-hydroxymethyl oxetane (manufactured by To a Gosei (Synthesis) K.K.), 1,4-bis{[(3-ethyl-3-oxetanyl)methoxy]methyl}benzene, di[1-ethyl (3-oxetanyl)]methyl ether, 3-ethyl-3-(2-ethyl cyclohexyl)oxetane, 3-ethyl-3-(phenoxy methyloxy)oxetane, oxetanyl silsesque oxetane, phenol novolak oxetane, 1,3-bis[(1-ethyl-3-oxetanyl)methoxy]benzene, and 4,4′-bis[(3-ethyl-3-oxetanyl)methoxy]biphenyl.

It is desirable for any of the photo-polymerizable compounds exemplified above to be mixed in an amount of 2 to 60% by weight based on the total weight of the recording layer. If the mixing amount of the photo-polymerizable compound is smaller than 2% by weight, it is impossible to increase sufficiently the refractive index of the recording region. On the other hand, if the mixing amount of the photo-polymerizable compound exceeds 60% by weight, the shrinkage of the recording region tends to be increased. It is more desirable for the mixing amount of the photo-polymerizable compound to be in the range of 10 to 50% by weight based on the total weight of the recording layer.

It is possible to add, as required, a photo radical polymerization initiating agent or a photo cationic polymerization initiating agent. The photo radical polymerization initiating agent includes, for example, an imidazole derivative, an organic azide compound, tithanocenes, organic peroxides, and thioxanthone derivatives. To be more specific, the photo radical polymerization initiating agent includes, for example, benzyl, benzoin, benzoin-ethyl ether, benzoin isopropyl ether, benzoin butyl ether, benzoin isobutyl ether, 1-hydroxy cyclohexyl phenyl ketone, benzyl methyl ketal, benzyl ethyl ketal, benzyl methoxy ethyl ether, 2,2′-diethyl acetophenone, 2,2′-dipropyl acetophenone, 2-hydroxy-2-methyl propiophenone, p-tert-butyl trichloro acetophenone, thioxanthone, 2-chloro thioxanthone, 3,3′4,4′-tetra(t-butyl peroxy carbonyl)benzophenone, 2,4,6-tris (trichloromethyl)-1,3,5-triazine, 2-(p-methoxy phenyl)-4,6-bis(trichloromethyl)-1,3,5-triazine, 2-[(p-methoxy phenyl)ethylene]-4,6-bis(trichloromethyl)-1,3,5-triazine, Irgacure Nos. 149, 184, 369, 651, 784, 819, 907, 1700, 1800 and 1850 manufactured by Ciba Specialty Chemicals di-t-butyl peroxide, dicumyl peroxide, t-butyl cumyl peroxide, t-butyl peroxide acetate, t-butyl peroxy phthalate, t-butyl peroxy benzoate, acetyl peroxide, isobutyl peroxide, decanoyl peroxide, lauroyl peroxide, benzoyl peroxide, t-butyl hydroperoxide, cumene hydroperoxide, methyl ethyl ketone peroxide, and cyclohexanone peroxide.

On the other hand, the photo cationic polymerization initiating agent includes, for example, salts such as an onium salt, a diazonium salt, a phosphonium salt, a sulfonium salt, an iodonium salt, CF₃SO₃⁻, p-CH₃PhSO₃⁻, and p-NO₂PhSO₃⁻. To be more specific, the photo cationic polymerization initiating agent includes, for example, di(p-tertiary butyl phenyl)iodonium trifluoromethane sulfonate, di(p-tertiary butyl phenyl)iodonium tetrafluoro borate, di(tertiary butyl phenyl)iodonium tetrafluoro arsenate, di(tertiary butyl phenyl)iodonium tetrafluoro antimonate, benzoin tosylate, o-nitrobenzyl p-toluene sulfonate, triphenyl sulfonium trifluoromethane sulfonate, tri(tertiary-butyl phenyl)sulfonium trifluoromethane sulfonate, and benzene diazonium p-toluene sulfonate.

It is desirable for any of the compounds used as the photopolymerization initiating agent to be mixed in an amount of 0.5 to 10% by weight based on the amount of the photo-polymerizable compound. If the mixing amount of the photopolymerization initiating agent is smaller than 0.5% by weight, the time required for the optical recording is rendered long. On the other hand, where the mixing amount of the photopolymerization initiating agent exceeds 10% by weight, the cured material becomes opaque, with the result that the light tends to be scattered, making it impossible to carry out the recording. It is more desirable for the mixing amount of the photopolymerization initiating agent to be in the range of 1 to 5% by weight.

It is possible to add as desired a sensitizing coloring matter such as cyanine, merocyanine, xanthene, cumarin or eosine, as well as a silane coupling agent and a plasticizer.

In the holographic optical recording medium according to the embodiment of the present invention, an information light and a reference light interfere with each other inside the recording layer so as to carry out the holographic optical recording-reproduction. It is possible for the recorded hologram (holography) to be any of a reflection type hologram (holography) and a transmission type hologram (holography). A two-beam interference method or a coaxial interference method can be employed for the interference between the information light and the reference light.

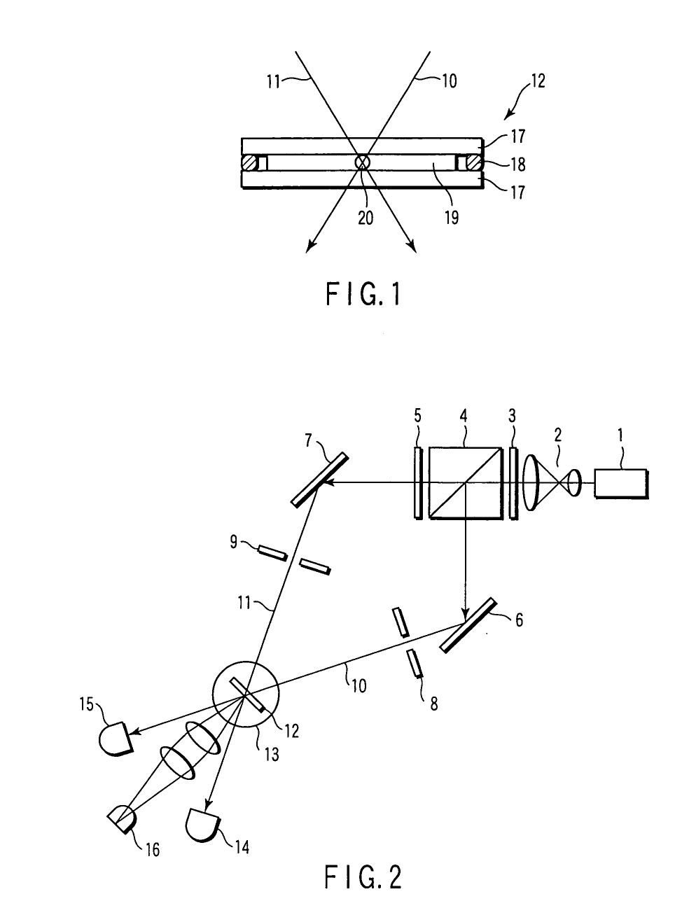

In the holographic optical recording medium according to the embodiment of the present invention, the information is recorded as shown in FIG. 1. Specifically, FIG. 1 schematically shows the holographic optical recording medium used for the two-beam interference holography together with the information light and the reference light in the vicinity of the holographic optical recording medium. As shown in the drawing, the holographic optical recording medium 12 comprises a pair of transparent substrates 17 formed of glass or polycarbonate. A spacer 18 and a recording layer 19 are held between these transparent substrates 17. The recording layer 19 has a prescribed polysilane skeleton structure as described previously.

The holographic optical recording medium 12 is irradiated with an information light 10 and a reference light 11. As shown in the drawing, these light beams 10 and 11 intersect each other within the recording layer 19, with the result that a transmission type hologram is formed in a modulating region 20 by the interference of the light beams 10 and 11.

FIG. 2 schematically exemplifies the construction of a holographic optical recording-reproducing apparatus. The holographic optical recording-reproducing apparatus shown in the drawing is a holographic type optical recording-reproducing apparatus utilizing the transmission type two-beam interference method.

The light beam emitted from a light source apparatus 1 is introduced into a polarized beam splitter 4 through a beam expander 2 and an optical element 3 for the rotatory polarization. The light source apparatus 1 can be used as a light source for emitting an optional light capable of interference within the recording layer 19 of the holographic optical recording medium 12. However, it is desirable for the light source apparatus 1 to emit a linearly polarized laser beam in view of, for example, the capability of the interference. The laser includes, for example, a semiconductor laser, a He—Ne laser, an argon laser or a YAG laser.

The beam expander 2 serves to straighten the polarizing direction of the light emitted from the light source apparatus 1, and the optical element 3 for the rotatory polarization serves to rotate the light expanded by the beam expander 2 so as to generate a light beam containing an S-polarized light component and a P-polarized light component. The optical element 3 for the rotatory polarization is provided by, for example, a ½ wavelength plate or a ¼ wavelength plate.

The S-polarized component of the light passing through the optical element 3 for the rotatory polarization is reflected by a polarized light beam splitter 4 so as to form the information light 10. On the other hand, the P-polarized component of the light passing through the optical element 3 for the rotatory polarization is transmitted through the polarized light beam splitter 4 so as to form the reference light 11. Incidentally, the direction of the optical rotation of the light incident on the polarized light beam splitter 4 is controlled by the optical element 3 for the rotatory polarization such that the information light 10 and the reference light 11 are made equal to each other in the intensity at the position of the recording layer 19 included in the holographic optical recording medium 12.

The information light 10 reflected from the polarized light beam splitter 4 is reflected again by a mirror 6 so as to pass through an electromagnetic shutter 8. Then, the recording layer 19 included in the holographic optical recording medium 12 held on a rotating stage 13 is irradiated with the information light 10.

On the other hand, the polarizing direction of the reference light 11 passing through the polarized light beam splitter 4 is swung by 90° by an optical element 5 for the rotatory polarization so as to form an S-polarized light. The S-polarized light thus formed is reflected by a mirror 7 and, then, passes through an electromagnetic shutter 9. Further, the recording layer 19 included in the holographic optical recording medium 12 held on the rotating stage 13 is irradiated with the S-polarized light such that the S-polarized light intersects the information light 10 within the recording layer 19 of the holographic optical recording medium 12. As a result, a transmission type hologram is formed as a refractive index modulated region 20.

In reproducing the information thus recorded, the electromagnetic shutter 8 is closed so as to intercept the information light 10 and, thus, to permit the transmission type hologram (refractive index modulated region 20) formed within the recording layer 19 of the holographic optical recording medium 12 to be irradiated with the reference light 11 alone. When passing through the holographic optical recording medium 12, the reference light 11 is partly diffracted by the transmission type hologram, and the diffracted light is detected by a light detector 15.

In the recording apparatus shown in the drawing, an ultraviolet light source 16 and an ultraviolet light irradiating optical system are arranged as the means for improving the diffraction efficiency after the holographic optical recording. An optional light source emitting a light beam capable of breaking the backbone chain structure of the polysilane can be used as the ultraviolet light source apparatus 16. It is desirable to use as the ultraviolet light source 16 a light-emitting device having a high ultraviolet light-emitting efficiency such as a xenon lamp, a mercury lamp, a high pressure mercury lamp, a mercury xenon lamp, a gallium nitride series light-emitting diode, a gallium nitride series semiconductor laser, an excimer laser, a third harmonic wave, which has a wavelength of 355 nm, of a Nd:YAG laser and a fourth harmonic wave, which has a wavelength of 266 nm, of a Nd:YAG laser.

The holographic optical recording medium according to the embodiment of the present invention can be suitably used for the recording-reproduction of a multi-layered light information. It is possible for the recording-reproduction of a multi-layered light information to be any of the transmission type reproduction and the reflection type reproduction.

The present invention will now be described more in detail with reference to Examples of the present invention.

### EXAMPLE 1

A raw material composition for a recording layer was prepared by mixing 16 g of a compound represented by chemical formula (6) given previously, which had an m:n ratio of 7:3 and which was used as a polysilane having a hydroxyl group, 13 g of “CELLOXIDE 2021” (trade name of 3,4-epoxy cyclohexenyl methyl-3′,4′-epoxy cyclohexene carboxylate manufactured by DAICEL CHEMICAL INDUSTRIES, LTD.), which was used as an epoxy compound, and 0.6 g of 2-methyl imidazole used as a curing catalyst, followed by defoaming the mixture.

The raw material composition for the recording layer thus obtained was poured into a clearance between two glass plates arranged to face each other with a spacer made of a Teflon sheet interposed therebetween. Then, the resultant structure was heated at 60° C. for 24 hours under a light-intercepted condition so as to obtain a test piece of a holographic optical recording medium including a recording layer having a thickness of 500 μm.

The test piece thus prepared was disposed on the rotating stage 13 of the holographic optical recording apparatus shown in FIG. 2 so as to record the hologram. A krypton laser having a wavelength of 350.7 nm was used as the light source apparatus 1. The optical spot size on the test piece was 5 mmφ for each of the information light 10 and the reference light 11, and the intensity of the recording light was controlled such that the sum of the intensities of the information light and the reference light was 5 mW/cm².

After the holographic optical recording, the information light 10 was intercepted by using the electromagnetic shutter 8 so as to permit the test piece to be irradiated with the reference light 11 alone. As a result, a diffracted light was recognized from the test piece so as to confirm that the transmission type hologram was recorded.

The hologram recording performance was evaluated by M/# (M number) representing the recording dynamic range. The parameter M/# is defined by the numerical formula given below by using ηᵢ. ηᵢ represents the diffraction efficiency from the i-th hologram at the time when the hologram of n-pages is subjected to an angle multiplexing recording-reproduction until the recording in the same region within the recording layer of the holographic optical recording medium is rendered impossible. The angle multiplexing recording-reproduction can be performed by irradiating the holographic optical recording medium 12 with a prescribed light while rotating the rotating stage 13.

$$M / \# = {\sum }_{i = 1}^{n} \sqrt{η} i$$

Incidentally, the diffraction efficiency n is provided by the internal diffraction efficiency that is represented by η=I_{d}/(Iₜ+I_{d}), where Iₜ denotes the light intensity detected by the light detector 14 and I_{d} denotes the light intensity detected by the light detector 15 when the holographic optical recording medium 12 was irradiated with the reference light 11 alone.

With increase in the value of M/#, the holographic optical recording medium exhibits a large recording dynamic range and, thus, is excellent in the multiplexing recording performance.

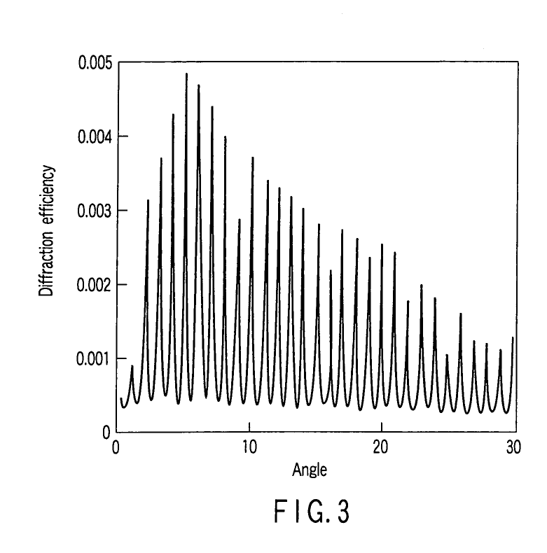

FIG. 3 exemplifies the reproduced signal in the case of performing the angle multiplexing recording-reproduction. Also, it is possible to calculate the rate of change in the volume of the holographic optical recording layer 19 between the state before the holographic optical recording and the state after the holographic optical recording on the basis of the shifting amount of the angle at which the diffraction efficiency from each hologram exhibits a peak.

In this Example, the test piece was once rotated by using the rotating stage 13 every time one page was recorded with the light exposure amount per page of the hologram set at 50 mJ/cm², and the holographic angle multiplexing recording of 30 pages was performed by repeating the rotation of the test piece. Further, after the test piece was left to stand for 5 minutes without performing the light irradiation for waiting for the completion of the reaction, the diffraction efficiency n was measured while sweeping the rotating stage so as to obtain the value of M/# and the rate of change in volume.

The value of M/# of the recording medium was found to be 5, and the volume expansion of the recording layer caused by the recording was found to be 0.20%.

In the recording layer included in the holographic optical recording medium manufactured in this Example, the polysilane was three-dimensionally crosslinked. Therefore, the polysilane was not dissolved in any kind of the solvent. Also, it was confirmed by the NMR, the IR spectrum, the UV absorption spectrum, and the elemental analysis that the recording layer was found to have a skeleton structure corresponding to chemical formula (2) given previously.

### EXAMPLE 2

A raw material composition for a recording layer was prepared by mixing 10 g of “PPSi” (trade name of a compound represented by chemical formula (12), manufactured by Osaka Gas Chemical Co., Ltd. and used as a polysilane having a hydroxyl group), 10 g of 1,4-butane diol glycidyl ether used as an epoxy compound, 3 g of diethylene triamine used as a curing agent, 0.7 g of “Irgacure 784” (trade name of a photo radical generating agent manufactured by Ciba Specialty Chemicals), and 0.15 g of t-butyl hydroperoxide (dilution with water: active oxygen 12%, manufactured by NOF CORPORATION), followed by defoaming the resultant mixture.

The raw material composition for the recording layer thus obtained was poured into a clearance between two glass plates arranged to face each other with a spacer made of a Teflon sheet interposed therebetween. Then, the resultant structure was maintained at room temperature for 48 hours under a light-intercepted condition so as to obtain a test piece of a holographic optical recording medium including a recording layer having a thickness of 500 μm.

The test piece thus prepared was disposed on the rotating stage 13 of the holographic optical recording apparatus as in Example 1 so as to record the hologram. The second harmonic wave of a Nd:YAG laser having a wavelength of 532 nm was used as the light source apparatus 1. The optical spot size on the test piece was 5 mmφ for each of the information light 10 and the reference light 11, and the intensity of the recording light was controlled such that the sum of the intensities of the information light and the reference light was 5 mW/cm².

After the holographic optical recording, the information light 10 was intercepted by using the electromagnetic shutter 8 so as to permit the test piece to be irradiated with the reference light 11 alone. As a result, a diffracted light was recognized from the test piece so as to confirm that the transmission type hologram was recorded.

Further, the value of M/# and the rate of change in volume were obtained by performing 30 pages of the holographic angle multiplexing recording-reproduction with the light exposure amount per page set at 50 mJ/cm² as in Example 1. The value of M/# of the recording medium was found to be 6, and the volume expansion of the recording layer caused by the recording was found to be 0.15%.

In the recording layer included in the holographic optical recording medium manufactured in this Example, the polysilane was three-dimensionally crosslinked. Therefore, the polysilane was not dissolved in any kind of the solvent. Also, it was confirmed by the NMR, the IR spectrum, the UV absorption spectrum, and the elemental analysis that the recording layer had a skeleton structure corresponding to chemical formula (1) given previously.

### COMPARATIVE EXAMPLE 1

A raw material solution for a recording layer was obtained by dissolving 5 g of the polysilane represented by chemical formula (6) in 20 g of toluene. Then, a glass plate was coated with the raw material solution so as to form a polysilane film. The coating was performed three times in an overlapping manner. However, since the polysilane film formed earlier was dissolved, it was difficult to increase the thickness of the polysilane film in spite of the coating operation that was performed three times in an overlapping manner. The polysilane film thus obtained was found to have a thickness of 9 μm. Then, a test piece of a holographic optical recording medium was prepared by further disposing a glass plate on the polysilane film.

The test piece thus prepared was disposed on the rotating stage 13 of the holographic optical recording apparatus as in Example 1 so as to record the hologram. A krypton laser having a wavelength of 350.7 nm was used as the light source apparatus 1. The optical spot size on the test piece was 5 mmφ for each of the information light 10 and the reference light 11, and the intensity of the recording light was controlled such that the sum of the intensities of the information light and the reference light was 5 mW/cm².

After the holographic optical recording, the information light 10 was intercepted by using the electromagnetic shutter 8 so as to permit the test piece to be irradiated with the reference light 11 alone. As a result, a diffracted light was recognized from the test piece so as to confirm that the transmission type hologram was recorded.

Further, the value of M/# and the rate of change in volume were obtained by performing 30 pages of the holographic angle multiplexing recording-reproduction with the light exposure amount per page set at 50 mJ/cm² as in Example 1. The value of M/# of the recording medium was found to be 0.2, and the volume expansion of the recording layer caused by the recording was found to be 0.60%.

The value of M/# for this Comparative Example was markedly smaller than that for each of Examples 1 and 2 described above. On the other hand, the volume expansion rate was increased in this Comparative Example. It is considered reasonable to understand that the unsatisfactory experimental data for this Comparative Example were caused by the situations that the thickness of the polysilane film was small, i.e., 9 μm, and that the polysilane was not crosslinked.

In addition, since the polysilane was not crosslinked in the recording layer included in the holographic optical recording medium manufactured for this Comparative Example, the recording layer was dissolved in a solvent such as toluene, making the film brittle after the light exposure.

### EXAMPLE 3

A raw material composition for a recording layer was prepared by mixing 10 g of a compound represented by chemical formula (10) in which the m:n ratio was 8:2, which was used as a polysilane having a hydroxyl group, 10 g of propylene glycol diglycidyl ether having an epoxy equivalent of 165 and used as an epoxy compound, 0.15 g of triphenyl phosphine used as a curing catalyst, 0.10 g of Irgacure 819 manufactured by Ciba Specialty Chemicals and used as a photo radical polymerization initiating agent, 1 g of N-vinyl pyrrolidone and 11 g of 2,4,6-tribromophenyl acrylate, followed by defoaming the resultant mixture.

The raw material composition for the recording layer thus obtained was poured into a clearance between two glass plates arranged to face each other with a spacer made of a Teflon sheet interposed therebetween. Then, the resultant structure was heated at 50° C. for 10 hours under a light-intercepted condition so as to obtain a test piece of a holographic optical recording medium including a recording layer having a thickness of 800 μm.

The test piece thus prepared was disposed on the rotating stage 13 of the holographic optical recording apparatus as in Example 1 so as to record the hologram. A semiconductor laser having a wavelength of 405 nm was used as the light source apparatus 1. The optical spot size on the test piece was 5 mmφ for each of the information light 10 and the reference light 11, and the intensity of the recording light was controlled such that the sum of the intensities of the information light and the reference light was 5 mW/cm².

After the holographic optical recording, the information light 10 was intercepted by using the electromagnetic shutter 8 so as to permit the test piece to be irradiated with the reference light 11 alone. As a result, a diffracted light was recognized from the test piece so as to confirm that the transmission type hologram was recorded.

Further, the value of M/# and the rate of change in volume were obtained by performing 30 pages of the holographic angle multiplexing recording-reproduction with the light exposure amount per page set at 50 mJ/cm² as in Example 1. The value of M/# of the recording medium was found to be 16, and the volume expansion of the recording layer caused by the recording was found to be 0.15%.

In the recording layer included in the holographic optical recording medium manufactured in this Example, the polysilane used was three-dimensionally crosslinked and, thus, not dissolved in any kind of the solvent. Also, it was confirmed by the NMR, the IR spectrum, the UV absorption spectrum, and the elemental analysis that the recording layer had a skeleton structure corresponding to chemical formula (3) given previously.

### EXAMPLE 4

A raw material composition for a recording layer was prepared by mixing 12 g of a compound represented by chemical formula (7) having an m:n ratio of 8:2 and used as a polysilane having a hydroxyl group, 10 g of “CELLOXIDE 2021” (trade name of 3,4-epoxy cyclohexenyl methyl-3′,4′-epoxy cyclohexane carboxylate manufactured by DAICEL CHEMICAL INDUSTRIES, LTD.) used as an epoxy compound and as a photo cationic polymerizable compound, 10 g of 2,4-dibromophenyl glycidyl ether used as an epoxy compound and as a photo cationic polymerizable compound, 0.25 g of triphenyl phosphine used as a curing catalyst, 0.5 g of di(tertiary butyl phenyl)iodonium trifluoromethane sulfonate used as a photo cationic polymerization initiating agent, and 0.1 g of merocyanine coloring matter represented by following chemical formula (13), followed by defoaming the resultant mixture.

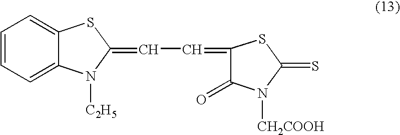

The raw material composition for the recording layer thus obtained was poured into a clearance between two glass plates arranged to face each other with a spacer made of a Teflon sheet interposed therebetween. Then, the resultant structure was heated at 60° C. for 8 hours under a light-intercepted condition so as to obtain a test piece of a holographic optical recording medium including a recording layer having a thickness of 500 μm.

The test piece thus prepared was disposed on the rotating stage 13 of the holographic optical recording apparatus as in Example 1 so as to record the hologram. The second harmonic wave, which had a wavelength of 532 nm, of a Nd:YAG laser was used as the light source apparatus 1. The optical spot size on the test piece was 5 mmφ for each of the information light 10 and the reference light 11, and the intensity of the recording light was controlled such that the sum of the intensities of the information light and the reference light was 5 mW/cm².

After the holographic optical recording, the information light 10 was intercepted by using the electromagnetic shutter 8 so as to permit the test piece to be irradiated with the reference light 11 alone. As a result, a diffracted light was recognized from the test piece so as to confirm that the transmission type hologram was recorded.

Further, the value of M/# and the rate of change in volume were obtained by performing 30 pages of the holographic angle multiplexing recording-reproduction with the light exposure amount per page set at 50 mJ/cm² as in Example 1. The value of M/# of the recording medium was found to be 7, and the volume expansion of the recording layer caused by the recording was found to be 0.12%.

In the recording layer included in the holographic optical recording medium manufactured in this Example, the polysilane used was three-dimensionally crosslinked and, thus, not dissolved in any kind of the solvent. Also, it was confirmed by the NMR, the IR spectrum, the UV absorption spectrum, and the elemental analysis that the recording layer had a skeleton structure corresponding to chemical formula (2) given previously.

### EXAMPLE 5

The recording medium having the hologram recorded therein in Example 4 was irradiated with ultraviolet light having an intensity of 10 mW/cm² by using a xenon lamp as the ultraviolet light source apparatus 14. Then, the value of M/# was measured by performing the angle reproduction alone as in Example 1. The value of M/# was found to be have been increased to 9 so as to confirm that the holographic optical recording performance was improved.

It should be noted that the polysilane bond was broken by the irradiation with the ultraviolet light so as to increase the contrast in the refractive index between the recording region and the non-recording region, with the result that the holographic optical recording function was improved as pointed out above.

### EXAMPLE 6

A raw material composition for a recording layer was prepared by mixing 10 g of a compound represented by chemical formula (10) having an m:n ratio of 1:0.8 and used as a polysilane having a hydroxyl group, 10 g of resorcinol diglycidyl ether used as an epoxy compound, 1 g of 2-methyl imidazole used as a curing agent, 0.8 g of N-vinyl pyrrolidinone used as a photo radical polymerizable compound, 1.4 g of N-vinyl carbazole, 0.070 g of Irgacure 784 (trade name of a photo radical polymerization initiating agent manufactured Ciba Specialty Chemicals), and 0.015 g of t-butyl hydroperoxide (dilution with water: active oxygen 12%, manufactured by Nippon Fat and Oil Inc.), followed by defoaming the resultant mixture.

The raw material composition for the recording layer thus obtained was poured into a clearance between two glass plates arranged to face each other with a spacer made of a Teflon sheet interposed therebetween. Then, the resultant structure was heated at 60° C. for 10 hours under a light-intercepted condition so as to obtain a test piece of a holographic optical recording medium including a recording layer having a thickness of 500 μm.

The test piece thus prepared was disposed on the rotating stage 13 of the holographic optical recording apparatus as in Example 1 so as to record the hologram. The second harmonic wave of a Nd:YAG laser having a wavelength of 532 nm was used as the light source apparatus 1. The optical spot size on the test piece was 5 mmφ for each of the information light 10 and the reference light 11, and the intensity of the recording light was controlled such that the sum of the intensities of the information light and the reference light was 5 mW/cm².

After the holographic optical recording, the information light 10 was intercepted by using the electromagnetic shutter 8 so as to permit the test piece to be irradiated with the reference light 11 alone. As a result, a diffracted light was recognized from the test piece so as to confirm that the transmission type hologram was recorded.

Further, the value of M/# and the rate of change in volume were obtained by performing 30 pages of the holographic angle multiplexing recording-reproduction with the light exposure amount per page set at 50 mJ/cm² as in Example 1. The value of M/# of the recording medium was found to be 8, and the volume expansion of the recording layer caused by the recording was found to be 0.12%.

In the recording layer included in the holographic optical recording medium manufactured in this Example, the polysilane was three-dimensionally crosslinked. Therefore, the polysilane was not dissolved in any kind of the solvent. Also, it was confirmed by the NMR, the IR spectrum, the UV absorption spectrum, and the elemental analysis that the recording layer had a skeleton structure corresponding to chemical formula (2) given previously.

### EXAMPLE 7

The recording medium having the hologram recorded therein in Example 6 was irradiated with ultraviolet light having an intensity of 10 mW/cm² by using a xenon lamp as in Example 5. Then, the value of M/# was measured by performing the angle reproduction alone as in Example 1. The value of M/# was found to be have been increased to 10 so as to confirm that the holographic optical recording performance was improved.

It should be noted that the polysilane bond was broken by the irradiation with the ultraviolet light so as to increase the contrast in the refractive index between the recording region and the non-recording region, with the result that the holographic optical recording function was improved as pointed out above.

### EXAMPLE 8

A raw material composition for a recording layer was prepared as in Example 6, except that a compound represented by chemical formula (7) having an m:n ratio of 1:1 was used as a polysilane having a hydroxyl group in place of the compound represented by chemical formula (10) used in Example 6. Then, a test piece of a holographic optical recording medium including a recording layer having a thickness of 200 μm was prepared as in Example 4 by using the raw material composition thus prepared.

Then, a hologram was recorded in the test piece thus obtained as in Example 6, followed by irradiating the test piece after the recording with a reference light alone. As a result, a diffracted light was recognized from the test piece so as to confirm that the transmission type hologram was recorded.

Further, the value of M/# and the rate of change in volume were obtained by performing 30 pages of the holographic angle multiplexing recording-reproduction with the light exposure amount per page set at 50 mJ/cm² as in Example 1. The value of M/# of the recording medium was found to be 3, and the volume expansion of the recording layer caused by the recording was found to be 0.10%.

In the recording layer included in the holographic optical recording medium manufactured in this Example, the polysilane was three-dimensionally crosslinked. Therefore, the polysilane was not dissolved in any kind of the solvent. Also, it was confirmed by the NMR, the IR spectrum, the UV absorption spectrum, and the elemental analysis that the recording layer had a skeleton structure represented by following chemical formula.

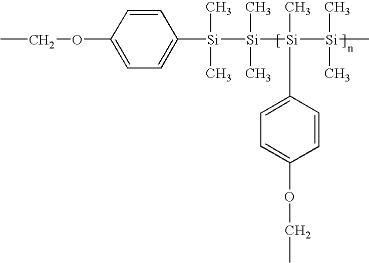

### EXAMPLE 9

The recording medium having the hologram recorded therein in Example 8 was irradiated with ultraviolet light having an intensity of 10 mW/cm² by using a xenon lamp as the ultraviolet light source apparatus 16. Then, the value of M/# was measured by performing the angle reproduction alone as in Example 1. The value of M/# was found to be have been increased to 4 so as to confirm that the holographic optical recording performance was improved.

It should be noted that the polysilane bond was broken by the irradiation with the ultraviolet light so as to increase the contrast in the refractive index between the recording region and the non-recording region, with the result that the holographic optical recording function was improved as pointed out above.

As described above in detail, the present invention provides a volume holographic optical recording medium having a high recording capacity, a high modulation of the refractive index, and a small change in the volume caused by the light irradiation. The present invention also provides a method of manufacturing a volume holographic optical recording medium having a high recording capacity, a high modulation of the refractive index, and a small change in the volume caused by the light irradiation. Further, the present invention provides a holographic optical recording method that permits recording information in a holographic optical recording medium having a recording layer containing polysilane in a high recording capacity and a high modulation of the refractive index while suppressing the change in volume.

Additional advantages and modifications will readily occur to those skilled in the art. Therefore, the present invention in its broader aspects is not limited to the specific details and representative embodiments shown and described herein. Accordingly, various modifications may be made without departing from the spirit or scope of the general inventive concept as defined by the appended claims and their equivalents.

1.-18. (canceled)

19. A method for recording a hologram, comprising:
irradiating a prescribed region of a recording layer included in a holographic optical recording medium with a first light so as to perform the recording, the recording layer having a skeleton structure containing a three-dimensionally crosslinked polysilane and a photo-polymerizable compound; and
irradiating the entire surface of the recording layer with a second light having a wavelength shorter than that of the first light.

20. The method for recording a hologram according to claim 19, wherein the first light is a light having a wavelength that permits the photo-polymerizable compound to be polymerized so, as to form a polymer, and the second light is a light having a wavelength that permits decomposing the three-dimensionally crosslinked polysilane.

21. The method for recording a hologram according to claim 19, wherein the skeleton structure contained in the recording layer included in the holographic optical recording medium is represented by following general formula (A): 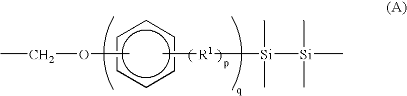
where R¹ denotes an atomic group selected from the group consisting of a linear or branched alkylene group having 1 to 10 carbon atoms and an arylene group having 1 to 10 carbon atoms, it being possible for a halogen atom or an alkoxy group to be substituted in R¹, and each of p and q is 0 or 1.
